(19) United States
(12) Patent Application Publication
(10) Pub. No.: US 2023/0257866 A1
(43) Pub. Date: Aug. 17, 2023

(54) METHOD FOR PRODUCING AN OPTICAL ELEMENT, OPTICAL ELEMENT, DEVICE FOR PRODUCING AN OPTICAL ELEMENT, SECONDARY GAS AND PROJECTION EXPOSURE SYSTEM

(71) Applicant: Carl Zeiss SMT GmbH, Oberkochen (DE)

(72) Inventors: Anastasia GONCHAR, Ulm (DE); Joern WEBER, Aalen (DE); Vitaliy SHKLOVER, Heidenheim (DE)

(21) Appl. No.: 18/128,672

(22) Filed: Mar. 30, 2023

Related U.S. Application Data
(63) Continuation of application No. PCT/EP2021/076033, filed on Sep. 22, 2021.

(30) Foreign Application Priority Data
Sep. 30, 2020 (DE) 10 2020 212 353.5

(51) Int. Cl. C23C 14/00; C23C 14/35; C23C 14/34; H01J 37/34; H01J 37/32; G21K 1/06; G03F 7/20

(52) U.S. Cl. CPC C23C 14/0036; C23C 14/352; C23C 14/3485; C23C 14/3471; C23C 14/3421; H01J 37/3405; H01J 37/32357; H01J 37/3417; H01J 37/345; H01J 37/3467; G21K 1/06; H01J 37/3485; G03F 7/70958; G03F 7/70316; G03F 7/70033; H01J 2237/332; G21K 2201/067

(57) ABSTRACT

A method for producing an optical element (2), in particular for a projection exposure system (400), according to which a protective layer (11) consisting of a protective material is applied to a surface of a main body (7) until a protective layer thickness is obtained. The main body (7) has a substrate (17) and a reflective layer (18) applied to the substrate (17). The protective layer (11) is at least substantially defect-free.

### CROSS-REFERENCE TO RELATED APPLICATIONS

This is a Continuation of International Application PCT/EP2021/076033, which has an international filing date of Sep. 22, 2021, which was published under PCT Article 21(2) in German, and the disclosure of which is incorporated in its entirety into the present Continuation by reference. The present Continuation Application also claims the priority of the German patent application no. 10 2020 212 353.5, the content of which is also fully incorporated herein by reference.

### FIELD OF THE INVENTION

The invention relates to a method of producing an optical element, especially for a projection exposure apparatus, whereby a capping layer formed from a capping material is applied to a surface of a main body until a capping layer thickness is attained, where the main body includes a substrate having a reflection layer applied to the substrate.

The invention further relates to an optical element, especially a mirror of a projection exposure apparatus, having a main body, wherein the main body has a substrate with a reflection layer applied to the substrate, and a capping layer formed from a capping material that has been applied to a surface of the main body and has a capping layer thickness.

The invention also relates to an apparatus for production of an optical element, especially for a projection exposure apparatus, comprising a target composed of a target material, a coating device configured to individualize particles of the target material with an ionized working gas for coating of a main body, where the main body has a substrate with a reflection layer applied to the substrate, and a working chamber for accommodating the main body and a vacuum device for forming a vacuum in the working chamber.

The invention further relates to the use of a secondary gas.

The invention also relates to a projection exposure apparatus for semiconductor lithography, having a radiation source and an optical unit which has at least one optical element.

### BACKGROUND

In a known manner, optical elements influence the properties of light rays that interact therewith. In order to avoid unwanted structures in the resulting wave fronts, exact surface processing of the optical elements is necessary. Optical elements include, for example, planar mirrors, hollow mirrors, curved mirrors, facet mirrors, convex lenses, concave lenses, convex-concave lenses, planar convex lenses and planar concave lenses. Known materials for optical elements, especially mirrors, include glass and silicon.

Projection exposure apparatuses have a multitude of optical elements. Especially when the optical elements are used in a microlithography EUV (extreme ultraviolet) projection exposure apparatus, the characteristics of the optical elements are of major importance.

The optical elements used herein are subject to a multitude of harmful influences that alter their characteristics and hence impair their ability to function, since the light modulated by the optical elements, for example an EUV mirror, firstly has a very small wavelength and hence the resulting wavefronts are perturbed even by the slightest impairments of the characteristics of the optical element. Secondly, the structures imaged on the projection surface are very small and hence likewise prone to the slightest change in the characteristics of the optical element. The harmful influences that can affect the optical element include, for example, EUV light, which has high energy, as well as the energy from this EUV light, which can damage the optical element on being absorbed therein.

In practice, it is known that EUV light can be generated by ionizing droplets of tin so as to form a plasma that emits EUV radiation in all directions.

The EUV radiation is collected, for example, by collector mirrors, which are exposed thereby not only to the EUV light emitted by the plasma but additionally to the damaging effect of tin ions and tin droplets. Moreover, the resultant plasma has a damaging effect on the collector mirrors by virtue of the presence, for example, of hydrogen ions and radicals, oxygen species and oxygen radicals, water including water in the gas phase, nitrogen species and nitrogen radicals, noble gases and noble gas ions, and the reaction products of the gases mentioned.

Furthermore, optical elements in an EUV projection exposure apparatus are exposed to impurities, for example hydrocarbons. In the region of the tin plasma, temperatures are also very high, which can lead, as a result of thermal expansion, especially different thermal expansion of different elements of the optical element, especially of the collector mirror, to warpage, to distortion and, in particular, to consequent damage.

Cleaning media that are used to clean the optical elements, for example to remove tin impurities and/or hydrocarbon impurities, frequently likewise have a damaging effect on the optical elements.

The abovementioned damaging effects may be manifested in the optical element by formation of blisters in the coatings and/or by the detachment of layers of the coatings and/or by the application of an unwanted layer of tin and unwanted mixing of the layer materials that form these layers with tin.

In order to prevent the damaging effects mentioned from impairing optically relevant layers of the optical element, it is common practice to provide the optical element with a capping layer.

U.S. Pat. No. 8,501,373 B2 describes passivation of a multilayer mirror for EUV lithography.

It is also common practice for the optical element to provide a reflection layer system on top of a substrate, atop of which system in turn one or more barrier layers are applied. The capping layer accordingly has the function of protecting not only the at least one barrier layer beneath but also the reflection layer system below that from outside influences.

However, the capping layer itself is likewise subject to the same damaging effects, and therefore damage may therefore also be observable on the capping layer itself.

The prior art discloses that the capping layer is formed by sputtering.

### SUMMARY

A disadvantage of the prior art is that the capping layers produced according to the prior art have only a short service life under the damaging influences mentioned. In particular, capping layers produced according to the prior art may show damage, such as blister formation, layer detachment, tin coverage and mixing with tin, even after a short period of time.

Further disadvantages of methods of producing a capping layer that are known from the prior art are oxidation and/or mixing of layers beneath the capping layer during a process of deposition of the capping layer. The oxidation and/or mixing may lead here to a reduction in the reflectivity of the optical element, especially a mirror.

A further disadvantage is, for example, damaging alteration of the target (“target poisoning”) when the capping layer is formed using reactive sputtering.

It is an object of the present invention to provide a method of producing an optical element that avoids the disadvantages of the prior art, and especially provides long-lived and serviceable capping layers.

It is a further object of the present invention to provide an optical element, especially a mirror of a projection exposure apparatus, which avoids the disadvantages of the prior art, and is especially long-lived and serviceable with regard to its optical properties.

It is a further object of the present invention to provide an apparatus for producing an optical element that avoids the disadvantages of the prior art, and especially enables formation of long-lived and serviceable capping layers.

It is a further object of the present invention to provide a secondary gas that avoids the disadvantages of the prior art, especially enabling formation of a long-lived and serviceable capping layer.

It is a further object of the present invention to provide a projection exposure apparatus for semiconductor lithography that avoids the disadvantages of the prior art, and especially enables long-lived and reliable operation.

In the method of the invention for producing an optical element, especially for a projection exposure apparatus, a capping layer formed from a capping material is applied to a surface of a main body until a capping layer thickness is attained, where the main body includes a substrate having a reflection layer applied to the substrate. According to the invention, the capping layer is at least virtually free of defects.

The inventors have recognized that capping layers of an optical element that are at least virtually defect-free have an advantageously long lifetime and advantageously high performance.

Defects may be understood to mean, for example, structural defects, for example pinholes, pores, grain boundaries and/or dislocations, and depositions of particles and/or contamination.

“Virtually free of defects” may mean, for example, a number of defects within an area of 100 μm² of less than 11.

The main body in the context of the invention should be considered to be formed from a substrate with a reflection layer applied to the substrate and optionally one or more barrier layers applied to the reflection layer, optionally over only part of the area. This means that, according to the invention, the capping layer is applied to a reflection layer—which is beneath the capping layer after the capping layer has been applied—if the surface of the main body is formed by a reflection layer, or the capping layer is applied to one or more barrier layers—which are beneath the capping layer after the capping layer has been applied—if the surface of the main body is formed by one or more barrier layers.

The formation of the main body from a substrate with a reflection layer applied to the substrate should at first be interpreted broadly in the context of the invention in that the main body has a substrate with a reflection layer applied to the substrate. The main body may especially also have a barrier layer, as described above.

In a narrow interpretation, the main body in the context of the invention should be considered to be formed solely from a substrate with a reflection layer applied to the substrate and optionally one or more barrier layers applied to the reflection layer, optionally over only part of the area.

The reflection layer may comprise multiple layers.

The multiple layers here may alternately comprise a material having a higher real part of a refractive index at a working wavelength of the optical element and a material having a lower real part of the refractive index at the working wavelength of the optical element.

It may be the case that the substrate comprises a material having a low coefficient of thermal expansion, for example Zerodur®, ULE® or Clearceram®. The optical element may be designed to reflect EUV radiation incident on the optical element at normal incidence, i.e. at angles of incidence a of typically less than about 45° to the surface normal. For the reflection of EUV radiation, a reflective multilayer system may have been applied to the substrate. The multilayer system may comprise alternately applied layers of a material having a higher real part of the refractive index at the working wavelength (also called “spacer”) and of a material having a lower real part of the refractive index at the working wavelength (also called “absorber”), where an absorber-spacer pair forms a stack. As a result of this construction of the multilayer system, there is simulation, in a certain way, of a crystal whose lattice planes correspond to the absorber layers at which Bragg reflection takes place. In order to ensure sufficient reflectivity, the multilayer system may comprise a number of generally more than fifty alternating layers.

The thicknesses of the individual layers and also of the repeating stacks may be constant over the entire multilayer system or else may vary, depending on what spectral or angle-dependent reflection profile is to be achieved. The reflection profile can also be influenced in a controlled manner by supplementing the basic structure composed of absorber and spacer with further more and less absorbent materials in order to increase the possible maximum reflectivity at the respective working wavelength. For this purpose, in some stacks, absorber and/or spacer materials may be mutually interchanged, or the stacks may be constructed from more than one absorber and/or spacer material. The absorber and spacer materials may have constant or varying thicknesses over all the stacks in order to optimize reflectivity. Furthermore, it is also possible to provide additional layers, for example as diffusion barriers, between spacer and absorber layers.

In one possible working example, in which the optical element has been optimized for a working wavelength of 13.5 nm, i.e. for an optical element which exhibits maximum reflectivity at a wavelength of 13.5 nm under substantially normal incidence of EUV radiation, the stacks of the multilayer system may comprise alternating silicon layers and molybdenum layers. In this system, the silicon layers correspond to the layers having a higher real part of the refractive index at 13.5 nm and the molybdenum layers to the layers having a lower real part of the refractive index at 13.5 nm. Depending on the exact value of the working wavelength, other material combinations, for example molybdenum and beryllium, ruthenium and beryllium, or lanthanum and B₄C, are likewise possible.

The reflection layer may especially comprise a reflection layer system, formed, for example, by a multilayer system composed of molybdenum-silicon (MoSi).

The one or more barrier layers that are optionally atop the reflection layer may be advantageous especially in the case of mirrors with normal incidence (NI).

The reflection layer may also be a coating, preferably a comparatively thick coating, for mirrors with grazing incidence (GI).

If there are complex layer systems between the substrate and the capping layer, for example a reflection layer system, and optionally one or more barrier layers, these are particularly prone to harmful effects, for example emanating from a plasma in the generation of EUV light.

Therefore, such layer systems profit in particular from a capping layer which is formed without defects by the method of the invention.

Moreover, production of such a main body precoated with a reflection layer and possibly one or more barrier layers is also particularly complex and hence also costly, and so it is particularly important for a capping layer to have a long service life.

Moreover, a capping layer should be applied to such a main body by a particularly reliable method, since an incorrectly applied capping layer in this case can have the effect that the main body can no longer be processed further.

In an advantageous development of the method of the invention, it may be the case that the capping layer is formed with sharp boundaries.

The inventors have established that a capping layer of an optical element having sharp interfaces with the main body has particularly long life and high performance. In particular, it may be the case that there is interpenetration of the capping material that forms the capping layer and the surface material that forms the surface of the main body by less than 10 nm, preferably less than 1 nm, preferably less than 0.1 nm.

In an advantageous development of the method of the invention, it may be the case that there is constant individualization of particles of a target material at at least one target by bombardment with ions of a working gas, with application of a discharge voltage for at least indirect ionization of the working gas and with formation of the capping layer in conjunction with a defect-preventing method.

An extension of a sputtering method by a defect-preventing method allows the capping layer, as known from the prior art, to be formed by sputtering methods, as a result of which, for example, use of sputtering systems known from the prior art permits particularly effective production of the capping layer. For avoidance of defects, the sputtering method is extended by a defect-preventing method in order advantageously to reduce the density of defects per unit area of the capping layer such that a virtually defect-free capping layer can be formed.

In an advantageous development of the method of the invention, it may be the case that the capping layer is formed from a capping material having a stoichiometric composition.

It may be advantageous when the capping material is in chemically pure form. The capping layer is thus formed from a chemically pure capping material, which minimizes defects, for example through the avoidance of lattice defects, which may be caused by the incorporation of chemically extrinsic particles. A stoichiometric composition is possessed by the elements that form the capping material in the stoichiometric ratio of those compounds that are intended to form the capping material. A stoichiometric composition of the capping material may thus refer to a chemical purity of the capping material.

In particular, use of oxides as capping material may be advantageous.

In an advantageous development of the method of the invention, zirconium oxide, ZrOₓ and/or titanium oxide, TiOₓ and/or niobium oxide, NbOₓ and/or yttrium oxide, YOₓ and/or hafnium oxide, HfOₓ and/or cerium oxide, CeOₓ and/or lanthanum oxide, LaOₓ and/or tantalum oxide, TaOₓ and/or aluminum oxide, AlOₓ and/or erbium oxide, ErOₓ and/or tungsten oxide, WOₓ and/or chromium oxide, CrOₓ and/or scandium oxide, ScOₓ and/or vanadium oxide, VOₓ, in pure form and/or as a mixture, may be provided as capping material.

In particular, it may also be the case that multicomponent mixtures of at least two or more of the oxides mentioned form the capping material.

It may especially be the case that the capping material consists of one of the aforementioned oxides or a mixture thereof, and any unavoidable impurities. The capping layer may preferably consist exclusively of the capping material.

The index x as stoichiometric coefficient in the aforementioned oxides describes the stoichiometric composition between the element that forms the oxide and the oxygen. The index x may be an integer, or else a rational number that results from the chemistry of the respective oxides.

In addition, in an advantageous development of the method of the invention, it may be the case that the capping layer thickness is 0.1 nm to 20 nm, preferably 0.3 nm to 10 nm, more preferably 0.5 to 3 nm.

Such a layer thickness in the context of the invention has particularly advantageous properties with regard to lifetime, performance and optical properties.

It may further be the case that the capping layer is formed from an amorphous and/or crystalline capping material. It may especially be the case that the capping material has both amorphous and crystalline structures, preferably with zones of amorphous structure and zones of crystalline structure arranged along the surface normal of the surface.

It may especially be the case that the optical element is a mirror with grazing incidence (GI) and/or that the optical element is a mirror for normal incidence (NI).

In an advantageous development, it may be the case that the particles of the target material form a capping material, move toward the main body and are deposited on the main body and form the capping layer.

If the capping material is formed by particles of a target material, the capping material may be provided in a particularly simple manner since it is identical to the target material. Thus, no further treatment of the target material is necessary, and the applying of the capping layer is therefore particularly efficient.

Such a method is referred to as sputtering or cathode atomization.

A comparison of gentle sputtering methods without any connection to optical elements is described in the publication Comparison of low damage sputter deposition techniques to enable the application of very thin a-Si passivation films, AIP Conference Proceedings 2147, 040009 (2019). Reference is made here to use in silicon solar cells.

In a further advantageous development of the method of the invention, it may be the case that a reaction gas reacts with the particles of the target material and forms particles of the capping material, and the particles of the capping material move toward the main body and are deposited on the main body and form the capping layer.

Creation of the capping material by a reaction of the particles of the target material with a reaction gas has the advantage that the increase in surface area of the target material that accompanies the individualization of the particles of the target material causes a reaction of the particles of the target material with the reaction gas to proceed in a particularly complete manner. If the capping material formed as a result is deposited on the raw material, a particularly advantageously chemically pure and hence stoichiometric capping layer is formed.

Such a method is frequently called reactive sputtering.

In an advantageous development of the invention, the reaction gas may be oxygen.

Use of oxygen as reaction gas allows the above-described oxides to be created in situ in a particularly advantageous manner.

In a further advantageous development of the invention, the defect-preventing method may be configured such that a potential of particles of the target material to cause damage after individualization of particles of the capping material and/or of ions and/or atoms and/or of electrons from the working gas and/or of particles of the reaction gas before they hit the main body and/or a capping layer that forms is reduced with regard to at least one damage parameter.

A configuration of the defect-preventing method to the effect that a potential of particles to cause damage is reduced with regard to at least one damage parameter has the advantage that damaging effects that can lead to defects on the capping layer and are mediated by particles are specifically reduced. In particular, at the microscopic level of particles, damage potential can be assigned particularly efficiently to one or more damage parameters. Influencing of the properties of the particles that contribute to the damage parameter can thus lead in a particularly targeted manner to a reduction in damage potential. Microscope analysis of the damage potential with regard to the damage parameters that lead to the damage potential enables specific reduction in the damage potential by influencing the damage parameters.

In an advantageous development of the invention, the at least one damage parameter may be a reduced kinetic energy which is preferably above a threshold.

If the damage parameter is identified as being a kinetic energy greater than a threshold, it is advantageously possible to reduce the kinetic energy of particles which is greater than that threshold. Particles, especially ions of the working gas, having particularly high energy, especially a kinetic energy above the threshold, can have a particularly damaging effect on the main body or the capping layer that forms. For example, ions of the working gas that are reflected with high kinetic energy at the target and hit the main body and/or the capping layer that forms can effectively shoot pinholes in the layer that forms. Penetration of the ions into the capping layer and/or the main body can also change the chemical composition of the capping layer and/or the main body. This can lead to the occurrence of defects. It is therefore advantageous either to reduce a kinetic energy above a damage-causing threshold and/or to stop particles having such a high kinetic energy from hitting the main body and/or the capping layer that forms. The two measures can reduce the damage parameter of the kinetic energy of particles that hit the main body and/or the capping layer that forms.

In an advantageous development of the invention, the capping layer may be formed by sputtering, with capture of particles charged in the defect-preventing method in a magnetic trap.

It may be advantageous to keep the charged particles, especially ions of the working gas, trapped in a magnetic trap via the action of a magnetic field. Since a Lorentz force acts particularly on particles with high speed and hence also high kinetic energy, a magnetic trap can advantageously prevent particularly high-speed particles from moving in the direction of the main body and/or the capping layer that forms in that these particularly high-speed particles are forced, for example, onto a path that points away from the main body and/or the capping layer that forms. It is thus possible to reduce the damage potential of these very high-speed particles.

In an advantageous development of the method of the invention, it may be the case that the defect-preventing method is configured as a facing-targets sputtering operation.

The supplementing of the sputtering method with a defect-preventing method in the form of an arrangement of two targets such that the targets face one another can achieve the effect that, for example, particles of high kinetic energy that are reflected at one target do not hit the main body and/or the capping layer that forms, but rather hit the second target facing the first target. This increases the probability that the particle moving at high speed will individualize a particle of the target material, and hence not exert any damaging effect on the main body and/or the capping layer that forms.

A combination of the configuration of facing targets and a magnetic trap can achieve the effect that charged particles having high kinetic energy are kept trapped, especially in the interspace between the facing targets.

Defects are also avoided by reducing a potential of the particles to cause damage.

Without having any connection to optical elements, facing-targets sputtering is known from publications EP 1 505 170 B1, DE 11 2008 000 252 T5, WO 2018/069091 A1 and EP 3 438 322 A1.

Publication EP 1 505 170 B1 describes the use of facing-targets sputtering in association with organic electroluminescence devices.

Publication DE 11 2008 000 252 T5 describes the use of facing-targets sputtering in association with formation of a thin film on a resin substrate.

Publication WO 2018/069091 A1 describes the use of facing-targets sputtering in association with the production of light-emitting diodes (LEDs).

Publication EP 3 438 322 A1 describes the use of facing-targets sputtering in association with the production of liquid-crystal displays and solar batteries.

In an advantageous development of the method of the invention, it may be the case that the ions of the working gas are formed in the defect-preventing method by a remote plasma source.

If a plasma source that forms ions of the working gas from the working gas is at a spatial distance from the main body and/or the capping layer that forms, it is less likely that very high-speed ions of the working gas will hit the main body and/or the capping layer that forms than if the plasma is formed in the immediate proximity of the target and/or the main body and/or the capping layer that forms. In particular, by transporting the ionized working gas to the target, it is possible to filter out high-energy particles.

It may be advantageous when the discharge voltage is reduced when a secondary gas is used in the defect-preventing method.

This can advantageously reduce acceleration and hence also kinetic energy and hence also a potential of charged particles to cause damage.

It may be advantageous when the capping layer is formed by sputtering, wherein the at least one target in the defect-preventing method takes the form of a dual-cathode magnetron with an active anode and/or a passive anode.

Through use of a dual-cathode magnetron, it is advantageously possible to trap high-energy charged particles via the formation of a magnetic field. In this case, in an execution of an anode of the magnetron as active anode, the anode brings about both the ionization of the working gas and the trapping of the high-energy particles. In an execution of the anode as passive anode, by contrast, merely the magnetic field of the magnetron is formed by the anode.

Without having any connection to optical elements, a dual-cathode magnetron for coating methods is known from publication EP 2 186 108 B1.

It may be advantageous when the capping layer is formed by sputtering, with ionization of the working gas in the defect-preventing method by Penning ionization with a secondary gas.

If the working gas is ionized by Penning ionization with a secondary gas, the secondary gas is first converted to an electronically excited state, and transfers its excitation energy to the working gas, which ionizes the latter. This can provide ions of the working gas without direct ionization of the working gas by the discharge voltage. This can lead to advantageously lower occurrence of particularly high-speed ions of the working gas.

Without having any connection to optical elements, Penning ionization in the sputtering method is known from the publication Influence of Unbalanced Magnetron and Penning Ionization for RF Reactive Magnetron Sputtering, Jpn. J. Appl. Phys. Vol 38 (1999) pp. 186-191, Part 1 No. 1A, January 1999.

Without having any connection to optical elements, Penning ionization in the sputtering method is also known from the publication Are the Argon metastables important in high power impulse magnetron sputtering discharges?, PHYSICS OF PLASMA 22, 113508 (2015).

Without having any connection to optical elements, Penning ionization in the sputtering method is also known from the publication Niobium films produced by magnetron sputtering using an AR-HE mixture as discharge gas Proceedings of the 1995 Workshop on RF Superconductivity, Gif-sur Yvette, France (SRF95C22), pp 479-483. What is described here is use for production of superconductive radiofrequency acceleration resonators.

It may be advantageous when the discharge voltage is reduced when a secondary gas is used in the defect-preventing method.

Advantageously, as a result of the Penning ionization, it is possible to reduce the discharge voltage; as a result, ionized particles of the working gas are accelerated to a lesser degree by the electrical field that results from the discharge voltage, and hence have a lower kinetic energy. This reduces the potential of charged particles to cause damage in a defect-preventing manner.

In an advantageous development of the invention, it may be the case that an electronic activation energy of the secondary gas is greater than an ionization energy of the working gas.

In order to assure that the Penning ionization can proceed particularly efficiently, it may be advantageous if the electronic activation energy of the secondary gas is greater than the ionization energy of the working gas, which makes it is possible to bring about a particularly high probability of the ionization of a particle of the working gas when it encounters an electronically activated particle of the secondary gas.

In particular, it may advantageously be the case that the secondary gas is a helium and the working gas is an argon.

It may be advantageous when the capping layer is formed by sputtering, and, in the defect-preventing method, the particles of the capping material after individualization and the ions and/or the atoms and/or the electrons from the working gas are assimilated in terms of energy by thermalization with the working gas.

If the probability of collisions of the particles before they hit the main body and/or the capping layer that forms is increased, it is likely that very high-speed particles will transfer a portion of their kinetic energy to other particles in the event of impact. In the case of frequent repetition of this process, the kinetic energies of the particles are therefore assimilated in terms of energy. In order to achieve a sufficiently high probability of impact, it is necessary to reduce an average free path length of the particles. This prevents an undecelerated impact of a very high-speed particle on the main body and/or the capping layer that forms.

It is advantageous when a pressure of the working gas is adjusted such that thermalization occurs in the defect-preventing method.

In particular, it is possible to increase the probability of collision of a high-speed particle with other not such high-speed particles by increasing the pressure of the working gas such that the density of the working gas is so high that an undecelerated collision of a high-speed particle with the main body and/or the capping layer that forms is reliably prevented.

Alternatively, it may be the case that a pressure of a thermalization gas is adjusted such that collision of high-speed particles of the working gas with particles of the thermalization gas is sufficiently likely to prevent the high-speed particles from hitting the main body and/or the capping layer that forms. In this case, the thermalization gas may, for example, be the secondary gas and/or another gas and/or a mixture of other gases. In particular, it may be the case that the thermalization gas is chemically inert, in order not to form any unwanted reaction products.

It is advantageous when the capping layer is formed by sputtering, wherein the at least one target is heated and/or melted in the defect-preventing method.

If the target is heated and/or melted, a lower kinetic energy may be sufficient to individualize the particles of the target. This also distinctly reduces the likelihood of occurrence of particles with particularly high energy that may have potential to cause damage. This is because the energy needed to individualize a particle of the target has already partly been provided by the thermal energy supplied to the target.

The use of a heated and/or molten target also makes it possible for particles of the target material and/or of the capping material formed from the target material to have an advantageously high kinetic energy, while the ions of the working gas have an advantageously low kinetic energy. A high kinetic energy of the particles of the target material can lead to an advantageously sharp formation of the boundaries between the surface of the raw material and the capping layer. It may therefore be advantageous when the particles of the capping material hit the surface of the main body and/or the capping layer that forms within a certain speed range. It is thus advantageous when the particles of the capping material are neither too slow nor too fast. When a heated and/or molten target is used, the particles of the capping material may be sufficiently fast to form a virtually defect-free capping layer and at the same time sufficiently slow to avoid defects in the capping layer.

In particular, it may be the case that the target is melted and is additionally heated until evaporation of the target material. In addition, heating of the target can advantageously contribute to sublimation of the target material.

Without having any connection to optical elements, a sputtering method with a molten target for coating methods is known from publication US 2017/0268122 A1.

Without having any connection to optical elements, a sputtering method with evaporation of the target for coating methods is known from publication Magnetron Deposition of Coatings with Evaporation of the Target, Technical Physics, 2015, Vol. 60, No. 12, pp. 1790-1795.

It is advantageous when the capping layer is formed by sputtering, with deceleration of the ions of the working gas by an electrical field in a mesh which is at an electrical potential in the defect-preventing method.

Advantageously, it is also possible to decelerate particularly high-speed charged particles with an electrical field of a mesh, which reduces the kinetic energy thereof and hence reduces the potential thereof to cause damage.

In particular, it is advantageous when the mesh is positioned in a potential flight path of a very high-speed particle in the direction of the main body and/or the capping layer that forms, and the mesh is at a potential having an opposite sign to that of the charge of the charged particle. As a result, a charged particle flying toward the mesh performs work against the electrical field and hence reduces its kinetic energy. A particle that passes through the mesh is subsequently accelerated away from the mesh, but, given a suitable positioning of the mesh at a suitable distance from the main body, is not able to build up sufficient kinetic energy to develop any potential to cause damage. Particles of the target material and/or the capping material that move toward the main body and form the capping layer, by contrast, are uncharged and can pass through the mesh.

The invention further relates to an optical element as claimed in claim 25.

The optical element of the invention, especially a mirror of a projection exposure apparatus, has a main body, wherein the main body has a substrate with a reflection layer applied to the substrate, and a capping layer formed from a capping material that has been applied to a surface of the main body. The capping layer here has a certain capping layer thickness. According to the invention, the capping layer is at least virtually free of defects.

Virtually defect-free formation of the capping layer on the surface of the main body can advantageously extend lifetime and performance of the optical element by reducing and/or preventing, for example, flaking of the capping layer and/or a layer beneath the capping layer which is a reflective layer for example.

The main body should also in the context of the invention be considered to be formed from a substrate with a reflection layer applied to the substrate and optionally one or more barrier layers applied to the reflection layer. This means that, according to the invention, the capping layer has been applied to a reflection layer—which is beneath the capping layer after the capping layer has been applied—if the surface of the main body has been formed by a reflection layer, or the capping layer has been applied to one or more barrier layers—which are beneath the capping layer after the capping layer has been applied—if the surface of the main body has been formed by at least one barrier layer.

The formation of the main body from a substrate with a reflection layer applied to the substrate should at first be interpreted broadly in the context of the invention in that the main body has a substrate with a reflection layer applied to the substrate. The main body may especially also have a barrier layer, as described above.

In a narrow interpretation, the main body in the context of the invention should be considered to be formed solely from a substrate with a reflection layer applied to the substrate and optionally one or more barrier layers applied to the reflection layer, optionally over only part of the area.

The optical element of the invention is particularly suitable for use in an EUV projection exposure apparatus. Use of the optical element as collector mirror may also be advantageous here.

In an advantageous development of the optical element of the invention, it may be the case that the capping layer has sharp boundaries.

Particularly sharp interfaces between the capping layer and the surface of the main body, i.e. between the capping layer and reflective layers beneath and/or at least one barrier layer, lead to a particularly advantageously marked chemical purity of the capping layer and of the reflective layers that form the surface of the main body and/or of the at least one barrier layer that forms the surface of the main body. In particular, this can prevent particles of the capping layer from penetrating into the underlying reflective layers and/or into the at least one underlying barrier layer of the main body, and/or particles of the reflective layers that form the surface of the main body and/or of the at least one barrier layer from penetrating into the capping layer.

In particular, it may be the case that there is interpenetration of the particles of the reflective layers and/or at least one barrier layer that form the surface of the main body and of the capping material by no deeper than 10 nm, preferably no deeper than 5 nm, preferably no deeper than 0.1 nm, preferably no deeper than one atomic layer, preferably less than one atomic layer.

In particular, sharpness of the interfaces can prevent loss of function both of the capping layer and of the reflective layers and/or the at least one barrier layer that form the surface of the main body.

In an advantageous development of the optical element of the invention, it may be the case that the capping material has a stoichiometric composition.

A capping material of stoichiometric composition and hence a capping layer of stoichiometric composition have the advantage that, in the case of such a marked particularly high chemical purity, defects on account of extrinsic atoms and extrinsic particles in the capping material are advantageously reduced.

In an advantageous development of the optical element of the invention, it may be the case that the capping layer is formed by facing-targets sputtering.

If the capping layer is formed by facing-targets sputtering, occurrence of unwanted defects is reduced and hence a virtually defect-free capping layer is formed.

In an advantageous development of the optical element of the invention, it may be the case that the capping layer is formed by sputtering in conjunction with Penning ionization.

If the capping layer is sputtered onto the surface of the main body, wherein the working gas in the sputtering method is ionized by Penning ionization, occurrence of particularly high-speed particles can be reduced and hence also the occurrence of unwanted defects in the capping layer.

In an advantageous development of the optical element of the invention, it may be the case that the capping layer is formed by sputtering in conjunction with thermalization.

In an advantageous development of the optical element of the invention, zirconium oxide, ZrOₓ and/or titanium oxide, TiOₓ and/or niobium oxide, NbOₓ and/or yttrium oxide, YOₓ and/or hafnium oxide, HfOₓ and/or cerium oxide, CeOₓ and/or lanthanum oxide, LaOₓ and/or tantalum oxide, TaOₓ and/or aluminum oxide, AlOₓ and/or erbium oxide, ErOₓ and/or tungsten oxide, WOₓ and/or chromium oxide, CrOₓ and/or scandium oxide, ScOₓ and/or vanadium oxide, VOₓ, in pure form and/or as a mixture, may be provided as capping material.

In particular, it may also be the case that multicomponent mixtures of at least two or more of the oxides mentioned form the capping material.

In addition, in an advantageous development of the optical element of the invention, it may be the case that the capping layer thickness is 0.1 nm to 20 nm, preferably 0.3 nm to 10 nm, more preferably 0.5 to 3 nm.

The invention further relates to an apparatus for production of an optical element as claimed in claim 33.

The apparatus of the invention for production of an optical element, especially for a projection exposure apparatus, comprises a target composed of a target material, a coating device configured to individualize particles of the target material with an ionized working gas for coating of a main body, where the main body has a substrate with a reflection layer applied to the substrate, and a working chamber for accommodating the main body and a vacuum device for forming a vacuum in the working chamber. According to the invention, at least one limiting device is provided in order to limit an energy of the particles after individualization and/or of the ions and/or of electrons and/or of atoms of the working gas that hit the main body. Such an apparatus has the advantage that defects caused by high-energy particles that hit the main body are reduced.

The coating device may especially be a cathode atomization device or sputtering device.

A capping layer of a main body formed in the apparatus of the invention is thus advantageously at least virtually free of defects or has a low level of defects.

In an advantageous development of the apparatus of the invention, it may be the case that the energy is a kinetic energy.

In an advantageous development of the apparatus of the invention, it may be the case that the limiting device is configured such that a density of the working gas in the vacuum is altered.

A kinetic energy of particles that hit the main body may especially be limited by increasing a probability of collision of high-speed particles with other particles before they hit the main body. This can be accomplished in that a density of the working gas in the vacuum is increased by comparison with an apparatus without a limiting device. As a result, more particles of the working gas are present in a unit of volume of the vacuum, which means that the probability of collision is increased, and the kinetic energy of high-speed particles, especially of the working gas, is assimilated.

Such an assimilation process is frequently referred to as thermalization.

In an advantageous development of the apparatus of the invention, it may be the case that the limiting device is configured as a Penning ionization device such that a secondary gas is fed into the working gas.

If a secondary gas is fed into the working gas, the working gas may be ionized by the electronically excited secondary gas by Penning ionization. In order to be able to feed the secondary gas into the working gas and/or the working chamber, a secondary gas supply device may be provided, which, depending on a pressure that exists in the chamber and/or an amount of working gas present in the chamber, supplies a certain amount of secondary gas to the working chamber and/or to the working gas.

In particular, it may be the case that between 10% and 1% by volume, preferably between 1% and 5% by volume, preferably 3% by volume, of secondary gas is fed into the working gas.

In a particularly advantageous manner, it may be the case that the working gas is an argon and a secondary gas is a helium.

In a further advantageous development of the apparatus of the invention, it may be the case that the limiting device is configured such that an electronic activation energy of the secondary gas is greater than ionization energy of the working gas.

In a further advantageous development of the apparatus of the invention, it may be the case that the limiting device takes the form of a magnetic trap.

Formation of the limiting device as a magnetic trap has the advantage that particularly high-speed charged particles, on account of the dependence of a Lorentz force on speed, can be stopped from hitting the main body in a particularly efficient manner in a magnetic trap.

In a further advantageous development of the apparatus of the invention, it may be the case that the limiting device takes the form of a heating device for heating and/or melting the target.

The limiting device may advantageously also take the form of a heating device, in order to heat and to melt the target, and hence to reduce the energy required to individualize a particle of the target material in the target. Hereby, it is advantageously possible to use ions of the working gas with a relatively low kinetic energy, which reduces the probability of high-energy particles hitting the raw material and/or the capping layer that forms. At the same time, the particles of the target material may have sufficiently high kinetic energy to form and at least virtually defect-free capping layer on the main body.

In an advantageous development of the apparatus of the invention, it may be the case that the limiting device is formed by a mesh at an electrostatic potential.

If the limiting device is formed by a mesh at a potential, high-speed charged ions of the working gas, given suitable choice of potential, can be decelerated by repulsive forces before they hit the main body and/or the capping layer that forms.

In an advantageous development of the apparatus of the invention, it may be the case that the limiting device takes the form of an afterglow device.

Without having any connection to optical elements, use of a plasma afterglow is described in publication U.S. Pat. No. 7,338,581 B2.

The use of an afterglow device can have the effect that, rather than the plasma glow, the plasma afterglow leads to individualization of the particles of the target material.

This can advantageously reduce potential damage caused by high-energy particles of the working gas and of high-energy particles of the target material.

In particular, the potential to cause damage can be reduced by significantly different plasma chemistry of the working gas in the plasma afterglow compared to the plasma chemistry of the working gas in the plasma glow.

The plasma afterglow of the working gas here is still a plasma and hence retains most of the properties of a plasma. However, potential of the working gas to cause damage can advantageously be reduced when the afterglow is used.

In an advantageous development of the apparatus of the invention, it may be the case that the afterglow device takes the form of a remote plasma source.

A remote plasma source is a plasma of the working gas which is spatially separated from outside electromagnetic fields that initiate a discharge of the working gas and hence bring about formation of the plasma. A plasma which is remote from the outside electromagnetic fields and is fed, for example, to the target exhibits an afterglow on contact with the target, which leads to reduced formation of high-energy particles of the target material and/or high-energy particles of the working gas.

In an advantageous development of the apparatus of the invention, it may be the case that the afterglow device takes the form of a pulsed plasma source.

As well as the above-described spatial separation of the plasma discharge and the individualization of the target material, this separation may also be brought about in the sense of time, i.e. in a time domain. The pulsed plasma source discharges the working gas for a short period. In the subsequent period of time, there is no active discharge via the plasma source, but merely an afterglow. A majority of the process of individualization of the particles of the target material is therefore brought about by a plasma afterglow of the working gas. This can reduce potential damage caused by high-energy particles of the working gas and/or of the target material.

A significant advantage of separation in time between discharge and contact with the target, by comparison with spatial separation, is that separation in time can be achieved in a closed apparatus. As a result, it is unnecessary to transport the afterglowing plasma from the plasma source to the target.

The apparatus of the invention can be made much more compact as a result in comparison with the remote plasma source.

In an advantageous development of the apparatus of the invention, it may be the case that the limiting device takes the form of two mutually opposing targets.

Such a facing-targets sputtering geometry has the advantage that high-energy particles of the working gas do not directly hit the coating and/or the optical element.

The invention further relates to a secondary gas for use in an apparatus as claimed and/or described herein.

The secondary gas of the invention is suitable for use in an apparatus and/or in a method as claimed and/or described herein. According to the invention, an electronic activation energy of the secondary gas is greater than an ionization energy of the working gas.

Hereby, it is advantageously possible to guarantee a high probability of ionization of a particle of the working gas on collision with an electronically activated particle of the secondary gas.

In an advantageous manner, it may be the case that the secondary gas is a helium and/or a neon and/or an argon and/or a krypton and/or a xenon and/or a mercury and/or a radon and/or a francium and/or a hassium. The ionization energies here are in descending order in the given sequence of the elements.

The person skilled in the art will be able to select suitable combinations of at least one working gas and at least one secondary gas from the substances specified.

In particular, it may be the case that helium and/or neon, which have a higher ionization energy than argon, are envisaged as secondary gas, with argon envisaged as working gas.

The invention further relates to a projection exposure apparatus as claimed and/or described herein.

Projection exposure apparatuses have a multitude of optical elements. Especially in the case of use of the optical elements with a microlithography EUV (extreme ultraviolet) projection exposure apparatus, it is advantageously possible to use an optical element produced at least partly by a method of the invention and/or the apparatus of the invention.

It may further be the case that the projection exposure apparatus of the invention includes at least one optical element of the invention, especially in the form of at least one mirror of the invention.

Features that have been described in association with one of the subjects of the invention, namely in the form of the method of the invention, the optical element of the invention, the apparatus of the invention, the secondary gas of the invention and the projection exposure apparatus of the invention, are also advantageously implementable for the other subjects of the invention. Advantages that have been mentioned in association with one of the subjects of the invention, namely in the form of the method of the invention, the optical element of the invention, the apparatus of the invention, the secondary gas of the invention and the projection exposure apparatus of the invention, may also be understood to relate to the other subjects of the invention.

It should additionally be pointed out that terms such as “comprising”, “having” or “with” do not preclude other features or steps. Furthermore, words such as “a(n)” or “the” which indicate single steps or features do not preclude a plurality of features or steps—and vice versa.

Working examples of the invention are described in detail below with reference to the drawing.

The figures each show preferred working examples in which individual features of the present invention are illustrated in combination with one another. Features of any working example are also implementable independently of the other features of the same working example, and may readily be combined accordingly by a person skilled in the art to form further viable combinations and sub-combinations with features of other working examples.

### BRIEF DESCRIPTION OF THE DRAWINGS

In the figures, functionally analogous or identical elements are given the same reference signs.

The figures show, in schematic form:

FIG. 1 an EUV projection exposure apparatus;

FIG. 2 an illustration in principle of a working example of a device in accordance with the invention;

FIG. 3 a further illustration in principle of a working example of a device in accordance with the invention;

FIG. 4 a further illustration in principle of a working example of a device in accordance with the invention;

FIG. 5 a further illustration in principle of a working example of a device in accordance with the invention;

FIG. 6 a further illustration in principle of a working example of a device in accordance with the invention;

FIG. 7 a further illustration in principle of a working example of a device in accordance with the invention; and

FIG. 8 an illustration in principle of an optical element fabricated in accordance with the invention.

### DETAILED DESCRIPTION

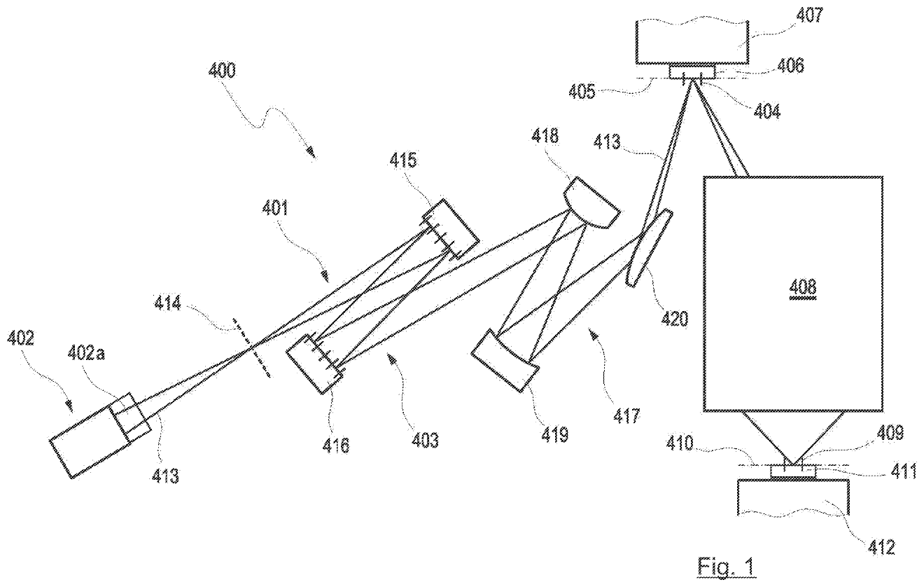

FIG. 1 shows, by way of example, the basic construction of an EUV projection exposure apparatus 400 for semiconductor lithography, for which the invention can preferably be employed. In particular, the invention may be employed in that at least one optical element of the projection exposure apparatus is produced by—as set out hereinafter—applying a capping layer formed from a capping material to a surface of a main body until a capping layer thickness has been attained, with formation of the capping layer in an at least a virtually defect-free manner.

An illumination system 401 of the projection exposure apparatus 400 comprises, as well as a radiation source 402, an optical unit 403 for the illumination of an object field 404 in an object plane 405. A reticle 406 disposed in the object field 404, held by a schematically illustrated reticle holder 407, is illuminated. A projection optical unit 408, illustrated merely schematically, serves to image the object field 404 into an image field 409 in an image plane 410. A structure on the reticle 406 is imaged onto a light-sensitive layer of a wafer 411 which is disposed in the region of the image field 409 in the image plane 410 and which is held by a wafer holder 412 that is likewise illustrated in part.

The radiation source 402 can emit EUV radiation 413, in particular in the range of between 5 nanometers and 30 nanometers, in particular 13.5 nm. Optically differently designed and mechanically adjustable optical elements are used for controlling the radiation path of the EUV radiation 413. In the case of the EUV projection exposure apparatus 400 illustrated in FIG. 1, the optical elements are in the form of adjustable mirrors in suitable embodiments that are mentioned merely by way of example hereinafter.

The EUV radiation 413 generated by the radiation source 402 is aligned with a collector 402a integrated in the radiation source 402 such that the EUV radiation 413 passes through an intermediate focus in the region of an intermediate focal plane 414 before the EUV radiation 413 arrives at a field facet mirror 415. Downstream of the field facet mirror 415, the EUV radiation 413 is reflected by a pupil facet mirror 416. With the aid of the pupil facet mirror 416 and an optical assembly 417 having mirrors 418, 419, 420, field facets of the field facet mirror 415 are imaged into the object field 404.

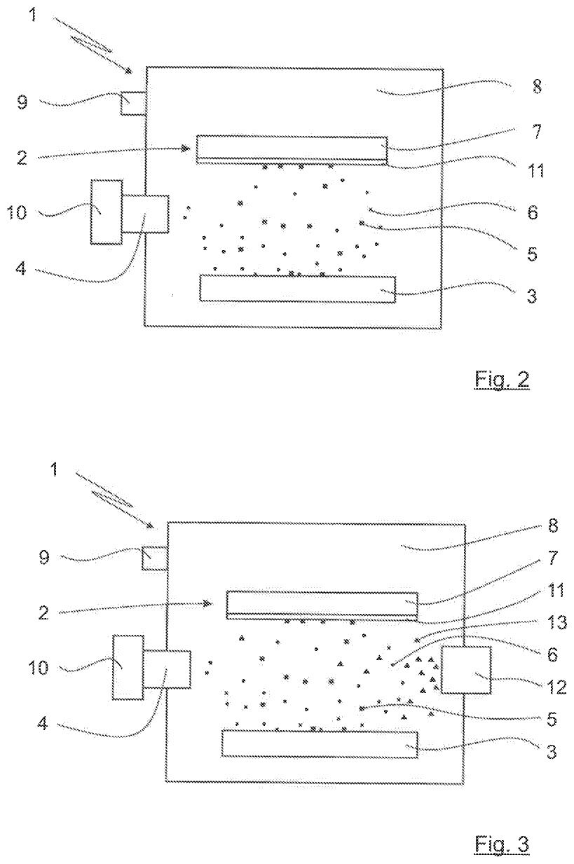

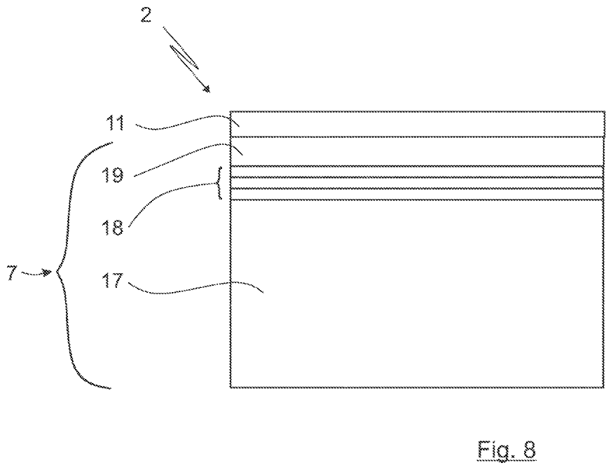

FIG. 2 in conjunction with FIG. 8 shows an illustration in principle of an apparatus 1 for production of an optical element 2, especially for a projection exposure apparatus 400, comprising a target 3 composed of a target material, a coating device 4 configured to individualize particles 5 of the target material via an ionized working gas 6 for coating of a main body 7, where the main body 7 has a substrate 17 with a reflection layer 18 applied to the substrate 17, and a working chamber 8 for accommodating the main body 7 and a vacuum device 9 for forming a vacuum in the working chamber 8. The apparatus further comprises a limiting device 10 in order to limit an energy of the particles 5 after individualization and/or of the ions and/or of electrons and/or of atoms of the working gas 6 that hit the main body 7.

The optical element 2 may especially be an optical element 2, 402a, 415, 416, 418, 419, 420 of the projection exposure apparatus 400.

In particular, the optical element 2 may also be a collector mirror 402a of the EUV projection exposure apparatus 400.

The main body 7 is formed here by a substrate 17 to which the reflection layer 18 composed of one or more materials has been applied, to which a barrier layer 19 has been applied in turn (see FIG. 8).

In another embodiment (not shown), it may be the case that the main body 7 is formed by a substrate 17, to which a reflection layer 18 composed of one or more materials has been applied, to which multiple barrier layers 19 have been applied in turn.

The apparatus 1 shown in FIG. 2 is suitable, for example, for performance of a method of producing an optical element 2, especially for a production exposure apparatus 400. This involves applying a capping layer 11 formed from a capping material to a surface of the main body 7 until a capping layer thickness is attained, where the main body 7 includes a substrate 17 having a reflection layer 18 applied to the substrate 17. The capping layer 11 here is formed at least virtually without defects.

In the working example shown for the apparatus 1, the method of producing the optical element 2 may be implemented such that the capping layer 11 is formed by sputtering. This involves constant individualization of particles 5 of the target material at the at least one target 3 by bombardment with ions of the working gas 6. In addition, a discharge voltage is applied for at least indirect ionization of the working gas 6, and the capping layer 11 is formed in conjunction with a defect-preventing method.

The capping layer 11, in the present working example, is formed from a capping material having a stoichiometric composition. In addition, in the present working example, the capping layer 11 is formed such that sharp boundaries are formed between the capping layer and the main body.

In the method implemented in the working example, the particles 5 of the target material form a capping material, move toward the main body 7, are deposited on the main body 7 and hence form the capping layer 11.

It may be the case that the particles 5 of the target material react with a reaction gas and hence form particles 5 of the capping material, and the particles 5 of the capping material subsequently move toward the main body 7 and are deposited on the main body 7 and hence form the capping layer 11.

In the present working example, it may be the case that the reaction gas is oxygen.

The limiting device 10, which, in the working example shown in FIG. 2, is part of the apparatus 1, is suitable for implementation of a defect-preventing method. In the defect-preventing method, a potential of particles 5 of the target material to cause damage after individualization and/or of particles 5 of the capping material and/or of ions and/or atoms and/or electrons of the working gas 6 and/or of particles of the reaction gas before they hit the main body 7 and/or before they hit the capping layer 11 that forms is reduced with regard to at least one damage parameter.

In particular, in the present working example, the at least one damage parameter is a kinetic energy which is preferably above a threshold. The limiting device 10 reduces the maximum kinetic energy that occurs.

The energy limited by the limiting device 10 is accordingly kinetic energy.

The limiting device 10, which, in the working example shown in FIG. 2, is part of the apparatus 1, is configured here such that a density of the working gas 6 in the vacuum is altered. An elevated collision frequency between the particles of the working gas 6 assimilates or limits the kinetic energy thereof.

The density of the working gas 6 in the present working example is increased by the limiting device 10 in that the limiting device supplies the working chamber 8 with working gas 6. In particular, it may be the case that the limiting device 10 takes the form of a metering device and/or valve device. Furthermore, it may also be the case in the present working example that the limiting device 10 supplies the working chamber 8 with a thermalization gas, which does not act as a working gas, but the particles of the working gas 6 collide with the particles thereof and hence the kinetic energy thereof is assimilated.

With the limiting device 10 detailed as part of the apparatus 1 shown in FIG. 2, it is possible to conduct a method in which the capping layer 11 is formed by sputtering, and, in the defect-preventing method, the particles 5 of the capping material after individualization and the ions and/or atoms and/or electrons from the working gas 6 are assimilated in terms of energy by thermalization with the working gas 6. In particular, with the limiting device 10 configured as a metering device, it is possible to adjust a pressure of the working gas 6 such that thermalization occurs in the defect-preventing method.

It may be the case that the limiting device 10 takes the form of an afterglow device. It may especially be the case that the afterglow device takes the form of a remote plasma source. The plasma source forms the working gas at a spatial distance from the target 3 and/or the capping layer 11 and subsequently moves it toward the target 3.

Individualization of the particles 5 of the target material takes place here via a plasma afterglow.

It may likewise be the case that the afterglow device takes the form of a pulsed plasma source. In this case, the working gas 6 is ionized merely in pulses over time. Individualization of the particles 5 of the target material is accordingly brought about for the most part via a plasma afterglow.

If the limiting device 10 takes the form of an afterglow device and especially of a remote plasma source, the device 1 is suitable for implementing a method by which the ions of the working gas 6 are formed by a remote plasma source in the defect-preventing method.

If the afterglow device takes the form of a pulsed plasma source, it is possible to implement a method whereby ions of the working gas 6 form a pulsed plasma in the defect-preventing method. In particular, it may be the case that, in the defect-preventing method, the at least one target takes the form of a dual-cathode magnetron.

FIG. 3 shows an apparatus 1 in which the limiting device 10 is configured as a Penning ionization device 12 such that a secondary gas 13 is fed into the working gas 6. The Penning ionization device 12 is configured here such that an electronic activation energy of the secondary gas 13 is greater than an ionization energy of the working gas 6.

An apparatus 1 configured as per the working example shown in FIG. 3 enables the performance of a method wherein the capping layer 11 is formed by sputtering in conjunction with a defect-preventing method. The defect-preventing method comprises ionizing the working gas 6 by Penning ionization with a secondary gas 13.

In order to prevent defects, it is possible here to reduce the discharge voltage if a secondary gas 13 is used.

For this purpose, an electronic activation energy of the secondary gas 13 is greater than the ionization energy of the working gas 6.

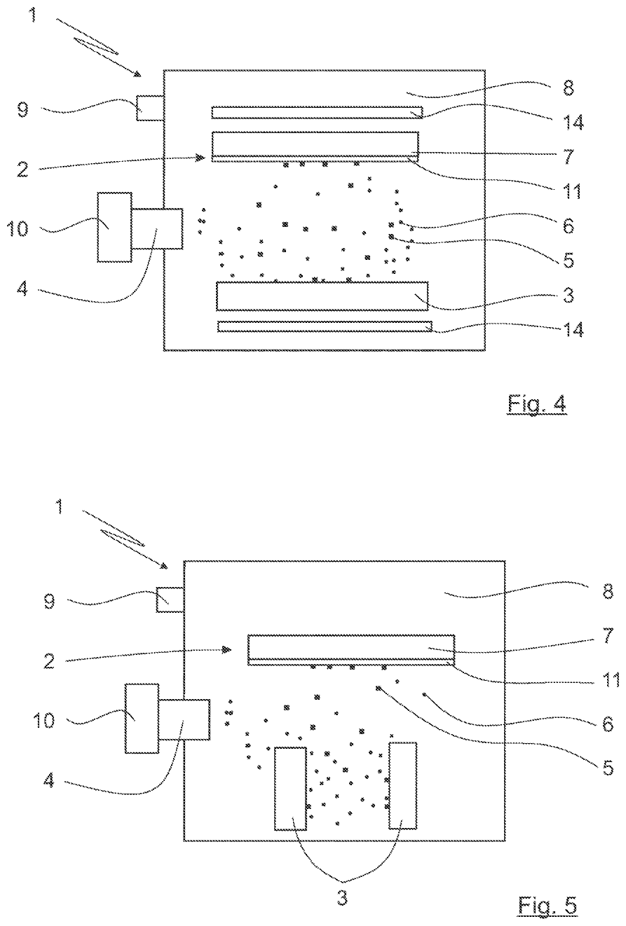

FIG. 4 shows an illustration in principle of a further working example of the apparatus 1. The limiting device 10 here takes the form of a magnetic trap 14. The magnetic trap 14 here forms a magnetic field such that charged particles having high kinetic energy are steered away from the capping layer 11.

In particular, the magnetic trap 14 is configured such that, in particular, ions of the working gas 6 having a high kinetic energy are held within a limited region of the working chamber 8 and especially do not interact with the capping layer 11.

The apparatus 1 shown in FIG. 4 can be used, for example, to perform a method wherein the capping layer 11 is formed by sputtering and wherein particles charged in the defect-preventing method, especially ions of the working gas, are trapped in a magnetic trap 14.

FIG. 5 shows an illustration in principle of an apparatus 1 wherein the limiting device 10 takes the form of two mutually opposing targets 3. Such an apparatus 1 can be used, for example, to conduct a method wherein the defect-preventing method is configured as a facing-targets sputtering operation. In particular, the targets 3 face one another such that, in particular, very high-speed ions of the working gas 6 cannot directly hit the main body 7 beneath the capping layer 11.

Instead, there is a high probability that very high-speed particles, especially ions of the working gas 6, will hit the respective opposing target 3.

FIG. 6 shows a further working example of the apparatus 1 wherein the limiting device 10 takes the form of a heating device 15 for heating and/or for melting the target 3. Such an apparatus 1 enables, for example, performance of a method whereby the capping layer 11 is formed by sputtering, and wherein the at least one target 3 is heated and/or melted in the defect-preventing method.

Melting of the target 3 requires lower energy for individualization of the particles 5 of the target material. Hereby, it is envisaged in the working example disclosed that the discharge voltage is reduced when the at least one target 3 is being heated and/or melted.

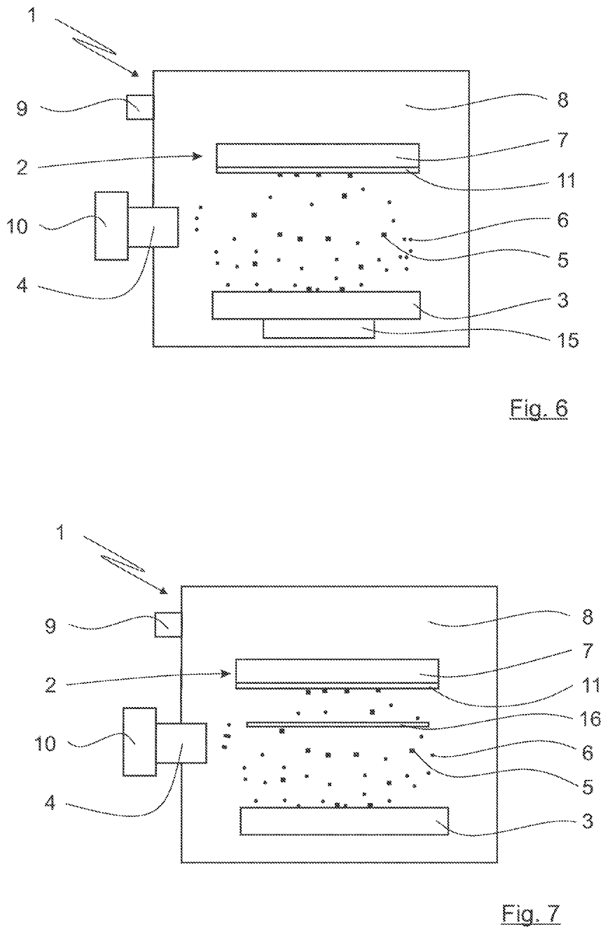

FIG. 7 shows an illustration in principle of a working example of the apparatus 1 wherein the limiting device 10 takes the form of a mesh 16 at an electrostatic potential. With such an apparatus, it is possible, for example, to conduct a method wherein the capping layer 11 is formed by sputtering, with deceleration of the ions of the working gas 6 by an electrical field in a mesh 16 which is at an electrical potential in the defect-preventing method.

Deceleration of charged particles, especially of the ions of the working gas 6, advantageously reduces the potential damage caused by ions of the working gas 6.

FIG. 8 shows an illustration in principle of an optical element 2, especially of a mirror of a projection exposure apparatus 400, having a main body 7, where the main body 7 has a substrate 17 with a reflection layer 18 applied to the substrate 17, and a capping layer 11 formed from a capping material that has been applied to a surface of the main body 7 and has a capping layer thickness, wherein the capping layer 11 is at least virtually free of defects.

The main body 7 is formed by a substrate 17 to which a reflection layer 18 composed of one or more materials has been applied, to which a barrier layer 19 has been applied in turn.

The capping layer 11 here has sharp boundaries both on the side facing the barrier layer 19 and on the side remote from the barrier layer 19.

In addition, the capping material that forms the capping layer 11 in the present working example has a stoichiometric composition. In the present working example, the capping layer 11 may be formed by facing-targets sputtering and/or by sputtering in conjunction with Penning ionization and/or by sputtering in conjunction with thermalization and/or by further methods that have been disclosed in the context of the invention.

The formation of the main body 7 from a substrate 17 with a reflection layer 18 applied to the substrate 17 should at first be interpreted broadly in the context of the invention in that the main body 7 has a substrate 17 with a reflection layer 18 applied to the substrate 17. The main body 7 may then especially, as shown in FIG. 8, also still have a barrier layer 19, as described above.

In a narrow interpretation, the main body 7 in the context of the invention should be considered to be formed solely from a substrate 17 with a reflection layer 18 applied to the substrate 17 and optionally one or more barrier layers 19 applied to the reflection layer 18, optionally over only part of the area.

### LIST OF REFERENCE SIGNS

1 Apparatus
2 Optical element
3 Target
4 Coating device
5 Particles of the target material
6 Working gas
7 Main body
8 Working chamber
9 Vacuum device
10 Limiting device
11 Capping layer
12 Penning ionization device
13 Secondary gas
14 Magnetic trap
15 Heating device
16 Mesh
17 Substrate
18 Reflection layer
19 Barrier layer
400 Projection exposure apparatus
401 Illumination system
402 Radiation source
402a Collector
403 Optical unit
404 Object field
405 Object plane
406 Reticle
407 Reticle holder
408 Projection optical unit
409 Image field
410 Image plane
411 Wafer
412 Wafer holder
413 EUV radiation
414 Intermediate focal plane
415 Field facet mirror
416 Pupil facet mirror
417 Optical assembly
418 Mirror
419 Mirror
420 Mirror

What is claimed is:

1. A method of producing an optical element, comprising:
forming a capping layer from a capping material by sputtering, with an uninterrupted individualization of particles of a target material at at least one target by bombardment with ions of a working gas, with application of a discharge voltage for at least indirect ionization of the working gas and with formation of the capping layer in conjunction with a defect-preventing method, and
applying the capping layer to a surface of a main body until a predetermined capping layer thickness is attained, wherein the main body includes a substrate having a reflection layer applied to the substrate, and wherein the formed capping layer is at least virtually free of defects,
wherein the defect-preventing method comprises a facing-targets sputtering operation.

2. The method as claimed in claim 1, wherein the capping layer is formed with sharp boundaries.

3. The method as claimed in claim 1, wherein the capping layer is formed from a capping material having a stoichiometric composition.

4. The method as claimed in claim 1, wherein the particles of the target material form the capping material, move toward the main body and are deposited on the main body to form the capping layer.

5. The method as claimed in claim 1, wherein a reaction gas reacts with the particles of the target material to form particles of the capping material, and the particles of the capping material move toward the main body and are deposited on the main body to form the capping layer.

6. The method as claimed in claim 5, wherein the reaction gas is oxygen.

7. The method as claimed in claim 5, wherein the defect-preventing method comprises reducing a potential of the particles of the target material to cause damage after the individualization and/or of particles of the capping material and/or of ions and/or atoms and/or electrons from the working gas and/or of particles of the reaction gas before hitting the main body and/or the capping layer that forms with regard to at least one damage parameter.

8. The method as claimed in claim 7, wherein the at least one damage parameter comprises a reduced kinetic energy.

9. The method as claimed in claim 1, wherein the forming of the capping layer comprises capturing particles charged in the defect-preventing method in a magnetic trap.

10. The method as claimed in claim 1, wherein the ions of the working gas are formed in the defect-preventing method by a remote plasma source.

11. The method as claimed in claim 1, wherein the ions of the working gas in the defect-preventing method form a pulsed plasma.

12. The method as claimed in claim 1, wherein the at least one target in the defect-preventing method comprises a dual-cathode magnetron with an active anode and/or a passive anode.

13. The method as claimed in claim 1, wherein the ionization of the working gas in the defect-preventing method comprises Penning ionization with a secondary gas.

14. The method as claimed in claim 13, wherein the defect-preventing method comprises using a secondary gas to reduce the discharge voltage.

15. The method as claimed claim 14, wherein an electronic activation energy of the secondary gas is greater than an ionization energy of the working gas.

16. The method as claimed in claim 1, wherein, in the defect-preventing method, the particles of the capping material after the individualization and the ions and/or atoms and/or electrons from the working gas are assimilated in terms of energy by thermalization with the working gas.

17. The method as claimed in claim 16, wherein a pressure of the working gas is adjusted such that thermalization occurs in the defect-preventing method.

18. The method as claimed in claim 1, wherein the defect-preventing method comprises heating and/or melting of the at least one target.

19. The method as claimed in claim 18. wherein the heating and/or melting of the at least one target comprises reducing the discharge voltage.

20. The method as claimed in claim 1, wherein the defect-preventing method comprises decelerating the ions of the working gas by an electrical field in a mesh which is at an electrical potential.

21. The method as claimed in claim 1, wherein the forming of the capping layer comprises providing: zirconium oxide, ZrOₓ and/or titanium oxide, TiOₓ and/or niobium oxide, NbOₓ and/or yttrium oxide, YOₓ and/or hafnium oxide, HfOₓ and/or cerium oxide, CeOₓ and/or lanthanum oxide, LaOₓ and/or tantalum oxide, TaOₓ and/or aluminum oxide, AlOₓ and/or erbium oxide, ErOₓ and/or tungsten oxide, WOₓ and/or chromium oxide, CrOₓ and/or scandium oxide, ScOₓ and/or vanadium oxide, VOₓ, in pure form and/or as a mixture, as the capping material.

22. The method as claimed in claim 1, wherein the predetermined capping layer thickness is 0.1 nm to 20 nm.

23. An optical element comprising:
a main body that has a substrate with a reflection layer applied to the substrate, and
a capping layer formed from a capping material by facing-targets sputtering and applied to a surface of the main body, wherein the capping layer has a capping layer thickness, and wherein the capping layer is at least virtually free of defects.

24. The optical element as claimed in claim 23, wherein the capping layer has sharp boundaries.

25. The optical element as claimed in claim 23, wherein the capping material has a stoichiometric composition.

26. The optical element as claimed in claim 23, wherein the capping layer is formed by sputtering in conjunction with Penning ionization.

27. The optical element as claimed in claim 23, wherein the capping layer is formed by sputtering in conjunction with thermalization.

28. The optical element as claimed in claim 23, wherein the capping layer comprises: zirconium oxide, ZrOₓ and/or titanium oxide, TiOₓ and/or niobium oxide, NbOₓ and/or yttrium oxide, YOₓ and/or hafnium oxide, HfOₓ and/or cerium oxide, CeOₓ and/or lanthanum oxide, LaOₓ and/or tantalum oxide, TaOₓ and/or aluminum oxide, AlOₓ and/or erbium oxide, ErOₓ and/or tungsten oxide, WOₓ and/or chromium oxide, CrOₓ and/or scandium oxide, ScOₓ and/or vanadium oxide, VOₓ, in pure form and/or as a mixture.

29. The optical element as claimed in claim 23, wherein the capping layer thickness is 0.1 nm to 20 nm.

30. An apparatus for producing an optical element, comprising:
a target composed of a target material,
a coating device configured to individualize particles of the target material with an ionized working gas for coating a main body, wherein the main body has a substrate with a reflection layer applied to the substrate,
a working chamber configured to accommodate the main body,
a vacuum device configured to form a vacuum in the working chamber, and
at least one limiting device comprising two mutually opposing targets and arranged to limit an energy of the particles after the individualizing and/or of the ions and/or electrons and/or atoms of the working gas that coat the main body.

31. The apparatus as claimed in claim 30, wherein the energy is a kinetic energy.

32. The apparatus as claimed in claim 30, wherein the limiting device is configured to alter a density of the working gas in the vacuum.

33. The apparatus as claimed in claim 30, wherein the limiting device is configured as a Penning ionization device such that a secondary gas is fed into the working gas.

34. The apparatus as claimed in claim 33, wherein the limiting device is configured such that an electronic activation energy of the secondary gas is greater than an ionization energy of the working gas.

35. The apparatus as claimed in claim 30, wherein the limiting device comprises a magnetic trap.

36. The apparatus as claimed in claim 30, wherein the limiting device comprises a heating device configured to heat and/or melt the target.

37. The apparatus as claimed in claim 30, wherein the limiting device comprises a mesh at an electrostatic potential.

38. The apparatus as claimed in claim 30, wherein the limiting device comprises an afterglow device.

39. The apparatus as claimed in claim 38, wherein the afterglow device comprises a remote plasma source.

40. The apparatus as claimed in claim 38, wherein the afterglow device comprises a pulsed plasma source.
